(19) United States
(12) Patent Application Publication
(10) Pub. No.: US 2009/0294066 A1
(43) Pub. Date: Dec. 3, 2009

(54) Dry Etching Apparatus

(76) Inventor: Jong Hun KIM, Bucheon-city (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/541,890

(22) Filed: Aug. 14, 2009

Related U.S. Application Data
(62) Division of application No. 11/220,972, filed on Sep. 6, 2005.

(30) Foreign Application Priority Data
Nov. 9, 2004 (KR) 10-2004-0090726

(51) Int. Cl. H01L 21/3065

(52) U.S. Cl. 156/345.51

(57) ABSTRACT

A plasma etching and/or cleaning apparatus is disclosed. The apparatus includes a pedestal for mounting a wafer thereon, a quartz insulator having the pedestal therein, a ceramic top cover covering a portion of the quartz insulator that is exposed to plasma, and a lower pedestal supporting the quartz insulator. By simply covering the quartz insulator with a ceramic cover, a decrease in particles may be observed, and the lifetime of the quartz pedestal is increased. Therefore, maintenance and repair costs of the apparatus can be reduced, thereby enhancing operation efficiency. Furthermore, since the production of particles can be reduced, a more uniform etch rate can be obtained when etching the wafer, thereby enhancing the yield of the semiconductor device. In a further embodiment, the ceramic cover has an upper surface free of holes adapted to contain an alignment pin.

This application is a divisional of U.S. patent application Ser. No. 11/220,972, filed Sep. 6, 2005 (Attorney Docket No. OPP-GZ-2005-0068-US-00), pending, which is incorporated herein by reference in its entirety. This application also claims the benefit of Korean Application No. P2004-90726, filed on Nov. 9, 2004, which is hereby incorporated by reference in its entirety.

### BACKGROUND OF THE INVENTION

1. Field of the Invention

The present invention relates to a dry etching and/or cleaning apparatus, and more particularly, to a plasma etching and/or cleaning apparatus that can etch and/or clean a semiconductor wafer using plasma, wherein particles accumulated on edge portions of a wafer and/or elsewhere in the apparatus may be reduced.

2. Discussion of the Related Art

In order to fabricate a semiconductor device, a wafer is formed and treated that may contain a polycrystalline silicon formed from, e.g., high purity amorphous silicon. Subsequently, a process of selecting the treated wafer is performed. In order to treat the wafer, unit processes (e.g., a photo process, an etching process, an expansion process, and a thin film process) are performed repeatedly.

Among such processes, the etching process selectively removes an uppermost layer of the wafer through a hole or opening in a photoresist layer or moves a pattern having the same size of the hole in the photoresist layer to the uppermost layer of the wafer.

In the step of fabricating a wafer, which is formed by processes of developing and etching a circuit pattern on a wafer surface, particles such as fine dust or moisture must be thoroughly removed because they may disturb and damage the formation of the circuit pattern. Generally, particles that may be produced due to external factors may be prevented beforehand by purifying the fabrication environment with cleaning equipment. However, particles that may be produced due to internal factors during the fabrication process cannot be easily prevented beforehand. Therefore, the wafer may be treated with numerous washing and/or cleaning steps in-between other fabrication steps.

The washing and cleaning processes of the wafer includes wet washing processes and dry cleaning processes. The wet washing process generally includes dipping the wafer into a solvent and/or rinsing the wafer so that the particles on the surface are removed. The dry cleaning process removes the particles by etching the surface of the wafer with plasma.

The wet washing process is effective for removing a photoresist layer that is coated on the surface of the wafer. However, management of the wet washing process is difficult, the cost required for the washing liquid increases the production cost, and the running time is long, thereby reducing productivity. Conversely, the dry etching (or dry cleaning) process is more widely used because of its increased anisotropic characteristic as the semiconductor device becomes more integrated, as opposed to the isotropic characteristic of the wet etching process.

The dry etching process includes a plasma etching method, ion beam milling method, and a reactive ion etching (RIE) method. The plasma etching method performs etching by using an etching gas instead of an etching liquid.

FIG. 1 illustrates a general cross-sectional view of a related art dry etching apparatus.

As shown in FIG. 1, the related art dry etching apparatus includes a loading unit 10. The loading unit 10 includes a titanium (Ti) pedestal 14 having a chamber (not shown) for etching a wafer surface and a wafer (W) mounted thereon, a quartz insulator 16 having the titanium pedestal 14 partially inserted therein and supported, and an aluminum pedestal 18 contacting and supporting a lower surface of a lower surface of the quartz insulator 16.

The titanium (Ti) pedestal 14 is formed in a cylindrical shape having a flat upper surface and an axis substantially identical to that of the wafer (W). The titanium pedestal 14 has a diameter smaller than that of the wafer (W) so that part of the wafer (W) contacts the titanium pedestal 14.

The quartz insulator 16 has a cylindrical groove or indentation identical to the shape of the titanium pedestal 14 so that it can be inserted in the upper portion of the quartz insulator 16 and held securely. The edge portion of the quartz insulator 16 next to a protrusion adjacent to the cylindrical indentation has a depressed (or sunken) shape. A plurality of alignment pins 19, spaced apart by a distance the same as the diameter of the wafer (W), contact the circumference of the wafer (W).

The aluminum pedestal 18 is an element formed in a round plate shape. The aluminum pedestal 18 contacts and supports the quartz insulator 16 for protection.

The operation of the related art dry etching apparatus having the above-described structure is as follows.

As the wafer (W) approaches the loading unit 10, the plurality of alignment pins 19 guides the wafer (W) so that it contacts the upper surface of the titanium pedestal 14 and is supported by the titanium pedestal 14 in the upper portion of the quartz insulator 16.

A gas injection hole (not shown) is formed in an upper surface of the chamber. An etching and/or cleaning gas such as argon (Ar) is injected therein, so as to etch the surface of the wafer. Due to a high frequency power applied thereto, the argon gas injected in the chamber is changed to a plasma (PL) state, and the plasma state reactive gas etches an exposed surface (e.g., an upper film or layer) of the wafer (W).

The quartz insulator 16 can be easily damaged even by the smallest impact, and its basic material is frequently damaged during the washing processes. And, since the edge portion on the upper surface of the quartz insulator 16 is exposed around the circumference of the upper surface of the titanium pedestal 14, to which the wafer (W) is directly contacted, the upper edge portion of the quartz insulator 16 can be etched due to a direct contact with the plasma, thereby producing a large amount of particles. The particles may accumulated on the edge portion of the wafer (W) and elsewhere in the chamber, including on the quartz insulator 16 itself, which can decrease the yield of the semiconductor devices on the wafer (W).

In addition, as the amount of particles produced is increased, a memory effect may be caused. More specifically, as a metal layer such as CoSi₂ is etched, the etched material adheres to the inside of the chamber or to its inner walls, which may also be formed of quartz. Then, the electrons or ions generated within the plasma may be grounded through the adhered particles, thereby causing the plasma to be unstable. Thus, when an oxide layer is targeted for etching under the same condition in a subsequent process, the etch rate may not be normal (or the same as the expected etch rate) due to the instability of the plasma.

Furthermore, although the particles that may accumulate on the edge portion of the wafer can be removed using a washing process, the economic effect that results from the increase in the yield of the semiconductor device provided by the wet washing process is insufficient. Therefore, the economic loss may become greater from wet washing than from disposing the specific parts formed on the edge portion of the wafer that are considered defective.

### SUMMARY OF THE INVENTION

Accordingly, the present invention is directed to a dry etching and/or cleaning apparatus that substantially obviates one or more problems due to limitations and disadvantages of the related art.

An object of the present invention is to provide a plasma etching and/or cleaning apparatus including a material resistant to plasma etching so as to reduce particles in the etching and/or cleaning chamber and reduce or prevent quartz insulator particles from being produced, thereby obtaining a relatively constant etch rate and increasing the yield of the semiconductor device.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a plasma etching apparatus includes a first (upper) pedestal adapted to hold (or mount) a wafer thereon, a quartz insulator having the first pedestal at least partly therein, a ceramic cover covering a portion of the quartz insulator that is exposed to plasma, a second (lower) pedestal supporting the quartz insulator, and a plurality of ceramic alignment pins protruding from the ceramic top cover, configured to align the wafer on the first metal pedestal. In a further embodiment, the ceramic cover has an upper surface free of holes adapted to contain an alignment pin.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a general cross-sectional view of a related art dry etching apparatus; and

FIG. 2 illustrates general cross-sectional view showing main parts of a dry etching apparatus according to the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

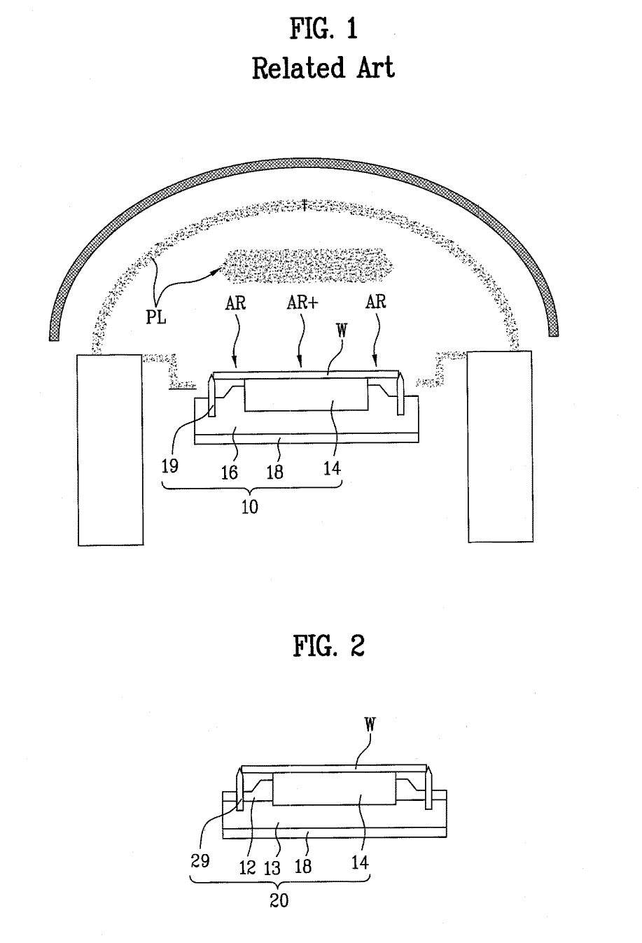

FIG. 2 illustrates a general cross-sectional view showing main parts of a plasma etching apparatus according to the present invention. The elements that are identical to the elements shown in FIG. 1 will be given the same reference numerals, and the description of the same will be omitted for simplicity.

As shown in FIG. 2, the dry etching apparatus according to the present invention includes a loading unit 20. The loading unit 20 comprises an upper pedestal 14 supporting a wafer (W) on its upper surface, a quartz insulator 13 and a ceramic cover 12 thereon, and a lower pedestal 18 contacting and supporting a lower surface of the quartz insulator.

The upper pedestal 14 may comprise or consist essentially of titanium or a titanium alloy, and the lower pedestal 14 may comprise or consist essentially of aluminum or an aluminum alloy, but either metal pedestal may comprise any electrically conducting material that is not etched substantially under the plasma etching and/or cleaning conditions employed. One reason for the upper pedestal comprising an electrically conducting material is that it generally holds the wafer thereon by electrostatic force.

The quartz insulator 13 generally supports the titanium pedestal 14 thereon, and may be further adapted to securely hold the upper pedestal 14 in a predetermined location. Ceramic cover 12 generally covers substantially the entire upper surface of the quartz insulator 13, and may comprise or consist essentially of an alumina-based ceramic (or other polished ceramic, such as silicon carbide). Such ceramics generally have a smoother surface than quartz, and thus, less surface area thereon to which particles can adhere.

In one embodiment, the ceramic cover 12 may include at least one pair of ceramic alignment pins 29 spaced apart by a distance substantially equal to the diameter of the wafer (W), so that the alignments pins 29 can guide the mounting of (or align) the wafer (W) onto the titanium pedestal 14.

The shape, alignment, and operation of the titanium pedestal 14 and the aluminum pedestal 18 are identical or similar to those of the related art plasma etching/cleaning apparatus.

The ceramic top cover 12 has an opening in its center portion, so that at least a lower portion of the titanium pedestal 14, which generally has a cylindrical shape, can penetrate therethrough. The quartz insulator 13 is adapted to support the titanium pedestal 14, and may have a depression or indentation therein to hold the upper pedestal 14 in place. In one embodiment, at least one pair of holes is formed in the ceramic top cover 12, one on each side thereof. The ceramic alignment pins 29 may be inserted therein, which align the wafer (W) into a predetermined position on the titanium pedestal 14.

The ceramic top cover 12 comprises or consists essentially of a ceramic which is not substantially etched even when exposed to plasma. The upper surface of the ceramic top cover 12 generally comprises a protruding portion and a recessed portion, thereby having a curved shape. The ceramic top cover 12 is aligned so as to cover the edge portion of the upper surface of the quartz insulator 13, which is to be exposed to plasma. Consequently, the ceramic top cover 12 may further include an alignment mechanism, such as a protruding lip on the outer periphery of the lower surface of the ceramic cover 12, or one or more complementary pin-and-hole, slot-and-groove or other matched shapes in which one shape is on the lower surface of the ceramic cover 12, and the complementary shape is on the upper surface of the quartz insulator 13.

The quartz insulator 13 generally has a cylindrical shape having an upper surface that is generally identical (or complementary) to the lower surface of the ceramic top cover 12. Therefore, when the quartz insulator 13 contacts the ceramic top cover 12, a curvature or protrusion does not form on the circumference of the structure. A central depression is in the center of the quartz insulator 13. This way, the lower portion of the titanium pedestal 14, which is inserted in the center opening of the ceramic top cover 12, can also be inserted in the central depression of the quartz insulator 13, so that the lower surface of the titanium pedestal 14 contacts the upper surface of the center (e.g., the central depression) of the quartz insulator 13. Thus, the titanium pedestal 14 can be stably fixed to or held by the quartz insulator 13.

The operation of the above-described plasma etching apparatus according to the present invention is as follows.

As the wafer (W) approaches the loading unit 20, the plurality of alignment pins 29 guide the wafer (W) so that it contacts the upper surface of the titanium pedestal 14 and is supported and held by the titanium pedestal 14 (which is on the upper portion of the quartz insulator 13) so that the wafer (W) has the same central axis as the titanium pedestal 14.

A gas injection hole in an upper surface of the chamber provides a reactive gas therein, so as to etch the surface of the wafer (W). Due to a high frequency power, the reactive gas injected in the chamber is changed (at least partly) to a plasma (PL) state, and the plasma state reactive gas etches or cleans an exposed film (or layer) of the wafer (W).

The generated plasma etches the wafer (W) and may approach areas of the quartz insulator 13 outside of the edge portion of the wafer (W). Except for the center portion in which the titanium pedestal 14 is inserted, the ceramic top cover 12 covers the entire upper surface of the quartz insulator 13 that may be exposed to the plasma. Therefore, the plasma cannot influence (i.e., cannot etch) the area (or edge portion) of the quartz insulator 13 covered by the ceramic top cover 12. Instead, only the ceramic top cover 12 is exposed to the plasma, which generally does not result in any significant number particles, since the ceramic material is relatively resistant to plasma etching, and relatively fewer particles adhere to the ceramic cover 12.

In another embodiment, the apparatus according to the present invention has a ceramic cover having a hole-free upper surface (i.e., that is free of holes having a size adapted to contain an alignment pin). Existing alignment detection systems (e.g., based on a three-point wafer alignment detector that can be installed in a pass chamber of a multi-chamber etching and/or dry cleaning apparatus) and current advanced robotics systems can ensure accurate placement of a wafer in a plasma etching chamber. As a result, plasma etching and/or cleaning apparatuses can be (retro)fitted with the present ceramic cover, such that the electrically insulating part of the wafer pedestal 20 contains no alignment pins or is not adapted for insertion of alignment pins.

In the dry etching and/or cleaning apparatus according to the present invention, by forming the ceramic top cover 12 so that it covers the upper edge portion of the quartz insulator 13, direct exposure of the quartz insulator 13 to plasma can be prevented, thereby preventing particles from being produced and/or reducing the number of particles in the plasma chamber.

As described above, the dry etching and/or cleaning apparatus according to the present invention has the following advantages. By simply changing the structure of the apparatus so that a ceramic cover covers the upper surface of the quartz insulator, a decrease in etching particles may be observed. Therefore, since the quartz insulator can be prevented from being etched, maintenance and repair costs of the dry etching and/or cleaning apparatus can be reduced, thereby enhancing operation efficiency. Furthermore, since the production of particles can be reduced or prevented, a relatively uniform etch rate can be obtained when etching the wafer, thereby enhancing the yield of the semiconductor device.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A plasma etching and/or cleaning apparatus, comprising:
a first metal pedestal configured to physically contact a wafer and support the wafer thereon by electrostatic force, wherein the first metal pedestal comprises titanium;
a quartz insulator adapted to support the first metal pedestal thereon;
a ceramic top cover covering an entire upper surface of the quartz insulator that is exposed to plasma; and
a plurality of ceramic alignment pins protruding from the ceramic top cover, configured to align the wafer on the first metal pedestal.

2. The apparatus according to claim 1, wherein the ceramic top cover surrounds the first metal pedestal.

3. The apparatus according to claim 2, wherein the ceramic top cover is adapted to retain the first metal pedestal in a predefined location on the quartz insulator.

4. The apparatus according to claim 1, further comprising a second metal pedestal contacting and supporting a lower surface of the quartz insulator.

5. The apparatus according to claim 1, wherein the second metal pedestal comprises aluminum.

6. The apparatus according to claim 5, wherein the second metal pedestal consists essentially of aluminum or an aluminum alloy.

7. The apparatus according to claim 1, wherein the first metal pedestal comprises titanium.

8. The apparatus according to claim 7, wherein the first metal pedestal consists essentially of titanium or a titanium alloy.

9. The apparatus according to claim 1, wherein the alignment pins are spaced apart by a distance substantially equal to a diameter of the wafer.

10. The apparatus according to claim 1, wherein the quartz insulator is further adapted to support and/or hold the plurality of ceramic alignment pins.

11. The apparatus according to claim 1, wherein the plurality of ceramic alignment pins are adapted to guide the wafer into a predetermined position on the first metal pedestal.

12. The apparatus according to claim 1, wherein the upper surface of the quartz insulator is identical to a lower surface of the ceramic top cover.
